(19) United States
(12) Patent Application Publication
(10) Pub. No.: US 2023/0137727 A1
(43) Pub. Date: May 4, 2023

(54) THERMAL RADIATION HEAT DISSIPATION DEVICE AND PREPARATION METHOD AND APPLICATIONS THEREOF

(71) Applicant: NATIONAL TSING HUA UNIVERSITY, Hsinchu (TW)

(72) Inventors: Meng-Ting Tsai, Hsinchu (TW); Yen-Jen Chen, Hsinchu (TW); Sih-Wei Chang, Hsinchu (TW); De-hui Wan, Hsinchu (TW); Hsuen-Li Chen, Hsinchu (TW)

(21) Appl. No.: 17/747,838

(22) Filed: May 18, 2022

(30) Foreign Application Priority Data
Oct. 29, 2021 (TW) 110140180

(51) Int. Cl. H05K 7/20

(52) U.S. Cl. CPC H05K 7/20454; H05K 7/20427; H05K 7/20463

(57) ABSTRACT

A thermal radiation heat dissipation device includes a radiation heat transfer pile including a plurality of polar dielectric material units of high energy gap, the polar dielectric material units each including at least one light scattering unit and a thermal radiation unit. The light scattering unit interacts with solar radiation to generate scattering of light. The thermal radiation unit interacts with thermal radiation to increase strength of thermal radiation.

### BACKGROUND OF THE INVENTION

### 1. Technical Field

The technical field relates to heat dissipation, and more particularly relates to a thermal radiation heat dissipation device and preparation method and applications thereof.

### 2. Description of Related Art

Global average temperature increases gradually, especially in sub-tropical nations such as Taiwan. Many air conditioners are used in the summer. But air conditioning can consume both electricity and energy. And in turn, it strains the supply of electricity. Global energy shortage is a big question. How to conserve energy is an issue to be addressed.

Earth can absorb sunlight and emit same to the air as long wave radiation. Heat balance is achieved when absorbed energy is equivalent to dissipated heat. Thermal radiation as one form of heat transfer plays a great role on Earth's temperature. Heat dissipation by thermal radiation is one of temperature decrease methods. Thermal radiation radiates heat to the air, i.e., decreasing temperature without electricity involved. Methods of thermal radiation-based heat dissipation include nighttime radiation heat dissipation and daytime radiation heat dissipation. In the daytime, heat absorbed by Earth is greater than that radiated to the air. Thus, Earth's temperature increases. In the nighttime, there is no sunlight and Earth continuously radiates heat. Thus, Earth's temperature decreases.

In the daytime, temperature increases as sunlight falls on buildings. Thus, there is a need of decreasing temperature, i.e., daytime radiation heat dissipation being more useful than night radiation heat dissipation. Temperature of an object may increase to a value greater than atmospheric temperature due to direct sunlight. Thus, benefits of daylight radiation heat dissipation are small. Currently, thermal radiation heat transfer systems for daytime use are complicated, expensive spectrum selective nanoscale photonic apparatuses. These photonic apparatuses for thermal radiation heat transfer are manufactured by precise nanoscale technologies including electron-beam lithography and vacuum deposit. However, such complicated, expensive apparatuses greatly limit mass production of thermal radiation heat dissipation devices. Thus, they do not satisfy great demand.

Further, some conventional thermal radiation heat dissipation devices are manufactured by composite materials including polymer. However, weathering of plastics, absorbing more sunlight due to excessive long periods of time exposed to ultraviolet, cracks, and degraded mechanical properties are drawbacks of polymer. Thus, the conventional thermal radiation heat transfer materials are disadvantageous due to no mass production and no possibility of prolonged period of time of outdoor use.

Thus, the need for improvement still exists.

### SUMMARY OF THE INVENTION

The disclosure is directed to a thermal radiation heat dissipation device for eliminating conventional drawbacks including the thermal radiation heat transfer material incapable of fulfilling need in the daytime and the material being not durable. The invention provides a thermal radiation heat dissipation device made of durable material, capable of being mass produced, decreasing absorbed heat of an object, and increasing heat dissipated from the object so that the thermal radiation heat dissipation device can effectively dissipate heat from the object in the daytime with strong thermal radiation.

The invention provides a piled, nanoscale fibrous structure. Many times of scattering of light occur on a surface of the fibrous structure when sunlight falls thereon. As a result, a highly diffuse reflection is generated. At the same time, the fibrous structure dissipates heat in the form of thermal radiation due to its high percentage of surface area. When an object is covered by the thermal radiation heat dissipation device of the invention and sunlight directly falls on the thermal radiation heat dissipation device of the invention, very little heat is absorbed by the object with most heat being dissipated from the object in the form of thermal radiation. As a result, temperature of the object is greatly decreased. The invention finds its applications in buildings, cooling warehouses, large factories, outdoor equipment, devices for maintaining low temperature, and electronic components.

For achieving above and other objects, the invention provides a thermal radiation heat dissipation device, comprising a radiation heat transfer pile including a plurality of polar dielectric material units of high energy gap, each of the polar dielectric material units including at least one light scattering unit and a thermal radiation unit, wherein the light scattering unit is configured to interact with solar radiation to generate scattering of light; and wherein the thermal radiation unit is configured to interact with thermal radiation to increase strength of thermal radiation.

In one of the exemplary embodiments, the polar dielectric material units are sub-wavelength structures.

In one of the exemplary embodiments, the sub-wavelength structures are piled to form a self-support structure.

In one of the exemplary embodiments, the sub-wavelength structures are piled to form a porous structure including a plurality of pores, and wherein thermal radiation passes through the pores to interact with surfaces of the polar dielectric material units.

In one of the exemplary embodiments, the sub-wavelength structure is a fibrous structure having a nanometric diameter.

In one of the exemplary embodiments, the fibrous structure includes a plurality of nanoparticles.

In one of the exemplary embodiments, the polar dielectric material unit further comprises a heat transfer unit so that heat is configured to transfer among the polar dielectric material units via the heat transfer unit.

In one of the exemplary embodiments, the heat transfer unit transfers heat to the thermal radiation unit for increasing radiant energy strength of the thermal radiation unit.

In one of the exemplary embodiments, a method of preparing the thermal radiation heat dissipation device comprising the steps of (a) providing both a solution having a precursor of fibrous material and a polymer for electrospinning; (b) uniformly mixing the solution to form a composite solution; (c) subjecting the composite solution to an electrospinning machine for forming a fibrous structure by injection; (d) controlling process parameters to adjust diameters of fibers of the fibrous structure and thickness of membranes of the fibrous structure; and (e) heating the fibrous structure to remove polymer and produce a nanoscale fibrous membrane.

In one of the exemplary embodiments, an electronic apparatus using the thermal radiation heat dissipation device, in a closed system the thermal radiation heat dissipation device is provided on an electronic component.

The invention has the following advantages and benefits in comparison with the conventional art: when an object is covered by the thermal radiation heat dissipation device and sunlight directly falls on the thermal radiation heat dissipation device, even without electricity being supplied, very little heat is absorbed by the object with most heat being dissipated in the form of thermal radiation, i.e., a minimum (almost no) energy consumption. As a result, temperature of the object is greatly decreased. The invention finds its applications in buildings, cooling warehouses, large factories, outdoor equipment, devices for keeping low temperature, and electronic components.

The above and other objects, features and advantages of the invention will become apparent from the following detailed description taken with the accompanying drawings.

### BRIEF DESCRIPTION OF THE DRAWINGS

FIG. 1 schematically depicts a thermal radiation heat dissipation device according to a first preferred embodiment of the invention;

FIG. 2 schematically depicts the polar dielectric material unit of the first preferred embodiment of the invention;

FIG. 3 is a cross-sectional view of the thermal radiation heat dissipation device of the first preferred embodiment of the invention;

FIG. 4 is an image of the polar dielectric material unit of the first preferred embodiment of the invention taken on a scanning electron microscope (SEM);

FIG. 5 is a cross-sectional view of another thermal radiation heat dissipation device of the first preferred embodiment of the invention provided on a curved substrate;

FIG. 6 includes one chart showing reflectance versus wavelength for the thermal radiation heat dissipation device of the first preferred embodiment of the invention on thermal radiation wavelength range of spectrum, and the other chart showing absorptance versus wavelength for the thermal radiation heat dissipation device of the first preferred embodiment of the invention on black body radiation wavelength range of spectrum; and

FIG. 7 is a cross-sectional view of a composite thermal radiation heat dissipation device according to a second preferred embodiment of the invention.

### DETAILED DESCRIPTION OF THE INVENTION

Embodiments of the invention will now be described, by way of example only, with reference to the accompanying drawings.

The invention is related to electromagnetic radiation of different wavelengths in which solar radiation means its wavelength located at any electromagnetic radiation in solar radiation wavelength range of spectrum; solar radiation wavelength range of spectrum means wavelength of 0.3 μm to 4 μm; thermal radiation means its wavelength located at any electromagnetic radiation in black body radiation wavelength range of spectrum, black body radiation wavelength range of spectrum means wavelength of about 4 μm to 25 μm, and atmospheric transparent window's wavelength range means wavelength of about 8 μm to 13 μm. It is understood that above wavelengths are exemplary, not limited. Different radiation wavelengths aim to explain principles and advantages of technical characteristics of the invention and do not aim to limit the invention to the specific wavelengths.

In the invention, diffuse reflection of material or structure means percentage of any incident electromagnetic radiation reflectively diffused from a surface. A perfect reflective body is defined as a body having 100% diffuse reflection. In the invention, high diffuse reflection means a material or structure has at least 60% diffuse reflection in a specific range, preferably, more than 80% diffuse reflection, and more preferably, more than 95% diffuse reflection.

In the invention, emissivity of a material or structure means efficacy of emitting electromagnetic radiation. A perfect black body emitter is defined as one has 100% emissivity. In the invention, high emissivity means a material or structure has at least 70% emissivity in a specific range, preferably, more than 80% emissivity, and more preferably, more than 95% emissivity.

In the invention, transmittance of a material or structure means ratio of electromagnetic wave penetrating the material or structure in a specific wavelength range. A perfect material or structure is defined as one has 100% transmittance. In the invention, high transmittance means a material or structure has about 60% transmittance in a specific range, preferably, more than 80% transmittance, and more preferably, more than 95% transmittance.

In the invention, sub-wavelength structure of a material or structure means the material or structure includes measure in at least one direction less than wavelength of electromagnetic radiation being compared. For example, measure in at least one direction is equal to or less than particle of any shape of wavelength having the maximum strength of material black body radiation, or diameter less than a structure formed of fibers of any shape having the maximum strength of material black body radiation. Wavelength of a material black body radiation having the maximum strength can be obtained by calculating material temperature based on Wien's displacement law.

In the invention, radiation heat transfer pile means a material having a high energy gap and being low in absorption of solar radiation wavelength range of spectrum. For example, but not limited to, the material is oxide such as Al₂O₃, ZnO, MgO, TiO₂, SiO₂, HfO₂, or ZrO₂; nitride such as A1N, hBN, cBN, Si₃N₄, or GaN; SiC; metallic chloride such as CaF₂, MgF₂, or BaF₂; carbonate such as CaCO₃ or CaMg(CO₃)₂ having CO₃²⁻; sulfate such as BaSO₄ or CaSO₄ having SO₄²⁻; or phosphate having PO₄³⁻.

In the invention, optical phonons are out-of-phase movements of the atoms in the lattice, one atom moving to the left, and its neighbor to the right. This occurs if the lattice basis consists of two or more atoms. They are called optical because in ionic crystals, such as sodium chloride, fluctuations in displacement create an electrical polarization that couples to the electromagnetic field. Hence, they can be excited by infrared radiation, the electric field of the light will move every positive sodium ion in the direction of the field, and every negative chloride ion in the other direction, causing the crystal to vibrate. Acoustic phonons are coherent movements of atoms of the lattice out of their equilibrium positions. If the displacement is in the direction of propagation, then in some areas the atoms will be closer, in others farther apart, as in a sound wave in air (hence the name acoustic). Displacement perpendicular to the propagation direction is comparable to waves on a string. If the wavelength of acoustic phonons goes to infinity, this corresponds to a simple displacement of the whole crystal, and this costs zero deformation energy. Acoustic phonons exhibit a linear relationship between frequency and phonon wave-vector for long wavelengths. The frequencies of acoustic phonons tend to zero with longer wavelength. Optical phonons have a non-zero frequency at the Brillouin zone center and show no dispersion near that long wavelength limit. This is because they correspond to a mode of vibration where positive and negative ions at adjacent lattice sites swing against each other, creating a time-varying electrical dipole moment.

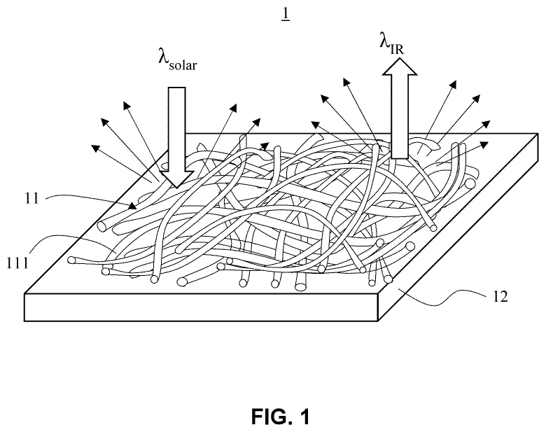

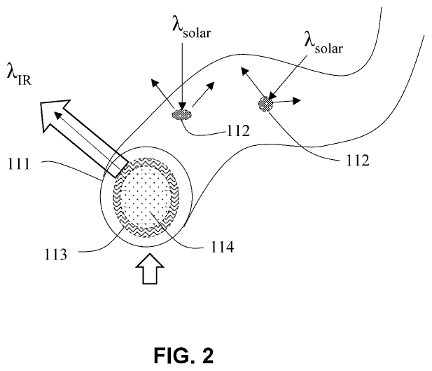

Referring to FIG. 1, a thermal radiation heat dissipation device 1 in accordance with a first preferred embodiment of the invention is shown and referring to FIG. 2, a polar dielectric material unit 111 in accordance with the first preferred embodiment of the invention is shown. Details thereof are discussed below.

The thermal radiation heat dissipation device 1 comprises a radiation heat transfer pile 11, the radiation heat transfer pile 11 including a plurality of polar dielectric material units 111. The radiation heat transfer pile 11 interacts with both solar radiation λₛₒₗₐᵣ and thermal radiation λ_{IR}. The radiation heat transfer pile 11 interacts differently with different wavelength ranges of electromagnetic radiation, i.e., having different optical characteristics at different electromagnetic radiation wavelength ranges. The radiation heat transfer pile 11 has high diffuse reflection at thermal radiation wavelength range of spectrum, and has high emissivity at black body radiation wavelength range of spectrum.

Referring to FIG. 2, on a surface of the polar dielectric material unit 111 there are provided with a plurality of light scattering units 112. Within the polar dielectric material unit 111, there is provided with a thermal radiation unit 113. The light scattering unit 112 is a diffused spot generated when the solar radiation λₛₒₗₐᵣ Interacts with the surface of the polar dielectric material unit 111. The thermal radiation unit 113 is generated when the thermal radiation λ_{IR} interacts with the polar dielectric material unit 111 and can increase strength of the thermal radiation λ_{IR}. The thermal radiation unit 113 emits the thermal radiation λ_{IR} from the polar dielectric material unit 111.

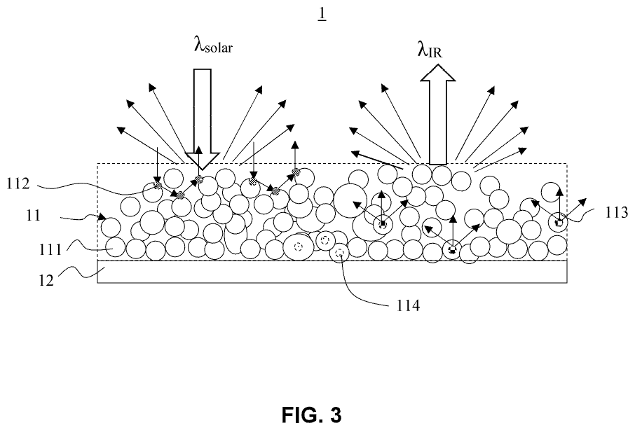

Referring to FIG. 3, it is a longitudinal sectional view of the thermal radiation heat dissipation device 1 of the first preferred embodiment of the invention. In the embodiment, the radiation heat transfer pile 11 includes a plurality of polar dielectric material units 111 shaped as a pile having a porous structure and a self-support structure. Pores of the porous structure allow the solar radiation λₛₒₗₐᵣ to pass through. The solar radiation λₛₒₗₐᵣ interacts with the light scattering unit 112 to scatter light. In detail, the solar radiation λₛₒₗₐᵣ enters the thermal radiation heat dissipation device 1 onto the light scattering unit 112 to cause scattering of light. The solar radiation λₛₒₗₐᵣ can cause many times of scattering of light on the light scattering units 112. In the invention, both the porous structure of the radiation heat transfer pile 11 and the greater surface area of the polar dielectric material units 111 cause the solar radiation λₛₒₗₐᵣ to generate high diffuse reflection. It is understood that the porous structure of the piled polar dielectric material units 111 may be tidy or untidy as long as the pores of the porous structure have high diffuse reflection. This is within the scope of the invention.

In the embodiment, the solar radiation λₛₒₗₐᵣ can generate high diffuse reflection in the pores of the porous structure. Further, the pores can adjust equivalent optical constant of the radiation heat transfer pile 11. Increasing sizes of the pores of the porous structure can decrease the equivalent optical constant of the radiation heat transfer pile 11. Emissivity of the thermal radiation λ_{IR} can be increased by decreasing both density of the fibers of the pile and porosity. It is understood that in other embodiments for achieving above objects, it is possible to fill matters having reflectivity lower than that of the polar dielectric material unit 111 so as to adjust the equivalent optical constant of the radiation heat transfer pile 11. In the invention, the porosity is between 30%-90%. In the invention, the piled polar dielectric material units 111 of the radiation heat transfer pile 11 form a self-support structure. Thus, there is no need of using polymer as substrate because polymer has many disadvantages including absorption at the wavelength ranges of 290-350 nm (i.e., ultraviolet) and 1500-2500 nm (i.e., infrared), thus greatly decreasing absorption of sunlight, polymer degradation, absorbing more sunlight due to excessive long periods of time exposed to ultraviolet, cracks, degraded mechanical properties, being not heat-resistant, being not flameproof, and being not appropriate for buildings.

In the invention, size of the polar dielectric material unit 111 is sub-wavelength structure. The sub-wavelength structure is defined as a fiber of any shape having a diameter equal to or less than the wavelength of electromagnetic radiation. The wavelength of the electromagnetic radiation is defined as wavelength of material black body radiation having the maximum strength. The sub-wavelength structure is, but not limited to, a fiber having a diameter between 50 nm and 8000 nm, and preferably, between 100 nm and 2000 nm. It is understood that in other embodiments, the polar dielectric material unit 111 is defined as a fiber having a measure in at least one direction equal to or less than the wavelength of electromagnetic radiation, or a fibrous structure having a plurality of nanoparticles. In the invention, it is not required to have all polar dielectric material units 111 to be the same size as long as the radiation heat transfer pile 11 includes a predetermined number of polar dielectric material units 111 having the characteristic of sub-wavelength structure. This is within the scope of the invention.

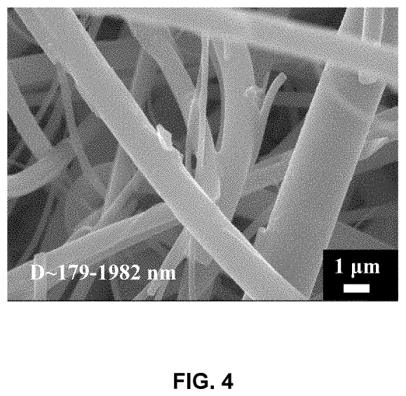

Referring to FIG. 4 in conjunction with FIGS. 1-3, it is an image of the polar dielectric material unit 111 of the first preferred embodiment of the invention taken on a scanning electron microscope (SEM). In the invention, the polar dielectric material units 111 are shaped as a pile, diameter of each fiber thereof is between 10-99 nanometers and 10-99 micrometers, and height of the pile is between 10-99 nanometers and several millimeters. When the solar radiation λₛₒₗₐᵣ interacts with surfaces of the fibers, a strong scattering of light is generated due to high overlapping of the polar dielectric material units 111 and the wavelength of the solar radiation λₛₒₗₐᵣ. Sunlight falling on the fibrous pile may generate diffuse reflection leaving its surface due to a great number of the light scattering units 112 of the fibrous pile. Thus, temperatures of both the fibers itself and its underlying matters do not increase due to absorption of the solar radiation λₛₒₗₐᵣ. In addition, since sizes of the fibers are equal to or less than a wavelength range of the thermal radiation λ_{IR}, heat can be dissipated in the form of infrared radiation (i.e., heat transfer). The greater of the thickness of the pile, the more of the number of the thermal radiation units 113 in the polar dielectric material unit 111 is. As a result, temperature of the thermal radiation heat dissipation device 1 decreases.

As shown in FIG. 2 specifically, it schematically depicts the polar dielectric material unit 111 of the first preferred embodiment of the invention interacting with both the solar radiation λₛₒₗₐᵣ and the thermal radiation λ_{IR}. The surface of the polar dielectric material unit 111 is provided with the plurality of light scattering units 11 because the fibrous structure has a high surface area to volume ratio. Great diffusion in many different directions is generated from the fibrous structure when the solar radiation λₛₒₗₐᵣ falls on the surface of the fibrous structure.

In the invention, the polar dielectric material unit 111 is a material having high energy gap. The polar dielectric material unit 111 absorbs little solar radiation from solar radiation wavelength range of spectrum and generates high diffuse reflection. At the same time, the fibrous structure greatly dissipates heat in the form of thermal radiation due to its large surface area. The polar dielectric material unit 111 includes the thermal radiation unit 113 which is an optical phonon. The optical phonon is generated when vibration of atoms in a lattice causes change of relative positions of the atoms. It is resonance when dipole between different atoms couples with electromagnetic wave of a specific frequency. It is useful to extract optical phonons from the resonant wavelength range. Optical phonons can increase emissivity of electromagnetic wave. In the embodiment, resonance is generated when the thermal radiation unit 113 interacts with the thermal radiation λ_{IR} of a specific frequency. The thermal radiation unit 113 can increase strength of the thermal radiation λ_{IR} of a specific frequency. In the invention, in comparison with polymer, the polar dielectric material unit 111 has a great density of the thermal radiation units 113. Further, with respect to the thermal radiation λ_{IR} of the specific frequency, the polar dielectric material unit 111 has greater radiant energy strength in comparison with polymer.

In the invention, the polar dielectric material unit 111 further comprises a heat transfer unit 114 which is an acoustic phonon. The acoustic phonons mean that the out-of-phase movements of the atoms in the lattice are without change of relative positions of atoms. The heat transfer unit 114 can transfer heat. Heat can be transferred between the polar dielectric material unit 111 and the heat transfer unit 114. That is, heat can be effectively transferred between different ones of the polar dielectric material units 111. The heat transfer unit 114 may increase heat transfer efficiency so that thermal resistance of the radiation heat transfer pile 111 can be decreased.

The heat transfer unit 114 can transfer heat to the thermal radiation unit 113 which in turn radiates the extracted thermal radiation λ_{IR} of the resonant wavelength range. As a result, strength of the thermal radiation λ_{IR} of a specific frequency is greatly increased.

As shown in FIG. 1 specifically, the thermal radiation heat dissipation device 1 is provided on a heat source 12. Heat produced by the heat source 12 transfers to the radiation heat transfer pile 11. Specifically, portions of the polar dielectric material units 111 of the radiation heat transfer pile 11 are in direct contact with the heat source 12. Thus, heat can be transferred to the polar dielectric material units 111. In the invention, the polar dielectric material units 111 of the fibrous structure have a great area in direct contact with the heat source 12. Thus, heat transfer is more effective. In addition, heat absorbed by one polar dielectric material unit 111 can transfer to other polar dielectric material units 111 by the heat transfer unit 114. Thermal resistance of the radiation heat transfer pile 11 is decreased to a minimum. Temperatures on two sides of the radiation heat transfer pile 11 decrease. The polar dielectric material unit 111 then radiates heat in the form of the thermal radiation λ_{IR} via the thermal radiation unit 113, thereby increasing strength of the thermal radiation λ_{IR} of a specific frequency. In the invention, the heat transfer unit 114 transfers heat to decrease thermal resistance of the radiation heat transfer pile 11. Further, the thermal radiation unit 113 can increase strength of the thermal radiation λ_{IR} so that thermal radiation heat transfer performance of the radiation heat transfer pile 11 can be increased and heat dissipated from the heat source 12 is greatly increased. In the invention, the thermal radiation heat dissipation device 1 can achieve the purposes of effective heat transfer in the form of thermal radiation.

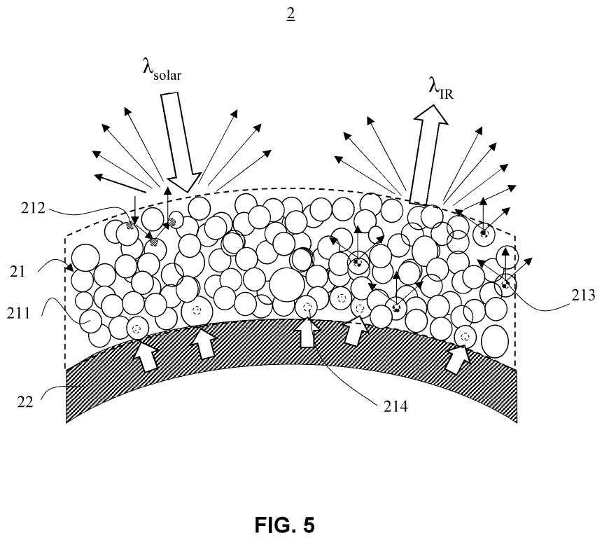

Referring to FIG. 5, it is a cross-sectional view of another thermal radiation heat dissipation device 2 of the first preferred embodiment of the invention provided on a curved substrate. The radiation heat transfer pile 21 of the thermal radiation heat dissipation device 2 includes a plurality of polar dielectric material units 211 shaped as a pile having a porous structure and a self-support structure. The radiation heat transfer pile 21 includes a plurality of light scattering units 212, a plurality of thermal radiation units 213 and a plurality of heat transfer units 214. Size of the polar dielectric material unit 211 is sub-wavelength structure and is a fibrous structure of any shape. The fibrous structure has a high surface area to volume ratio and is flexible due to its elongated fibers. The fibrous radiation heat transfer pile 21 is piled and flexible. The flexible structure is appropriate for uneven surface in use. The radiation heat transfer pile 21 is provided on a heat source 22. When the heat source 22 is curved, the radiation heat transfer pile 21 can be adhered to the heat source 22. The heat source 22 can transfer heat to the radiation heat transfer pile 21. In the invention, the nanoscale fibrous material is an inorganic material (e.g., oxide, chloride, semiconductor, or glass) or a composite material. Thus, the nanoscale fibrous material has the advantages of being light and flexible, having a great surface area and a high burning point (i.e., being flame retardant).

In the invention, the fibrous structure greatly increases the contact area between the polar dielectric material unit 212 and the heat source 12. Thus, heat transfer is more efficient. When the heat source 22 is bent, its surface area increases. Thus, the contact area between the polar dielectric material unit 21 and the heat source 22 is further increased. The heat transfer unit 214 can transfer heat from the polar dielectric material unit 21 to other polar dielectric material units 211. Thermal resistance of the radiation heat transfer pile 21 is decreased to a minimum because the heat transfer unit 214 can transfer heat. Temperatures on two sides of the radiation heat transfer pile 11 are decreased. The polar dielectric material unit 211 then radiates heat in the form of the thermal radiation λ_{IR} via the thermal radiation unit 213, thereby increasing strength of the thermal radiation λ_{IR} of a specific frequency.

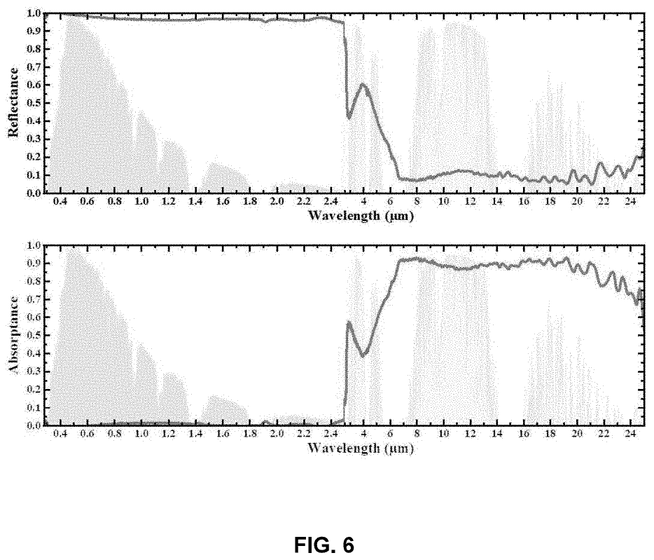

Referring to FIG. 6, it includes one chart showing reflectance versus wavelength for the thermal radiation heat dissipation device of the first preferred embodiment of the invention on thermal radiation wavelength range of spectrum, and the other chart showing absorptance versus wavelength for the thermal radiation heat dissipation device of the first preferred embodiment of the invention on black body radiation wavelength range of spectrum. The thermal radiation heat dissipation device has a reflectance of more than 95% at solar radiation wavelength range of spectrum and has an absorptance of 85%-90% at black body radiation wavelength range of spectrum respectively. The former means that it can block most sunlight and the later means that temperature can be decreased by thermal radiation.

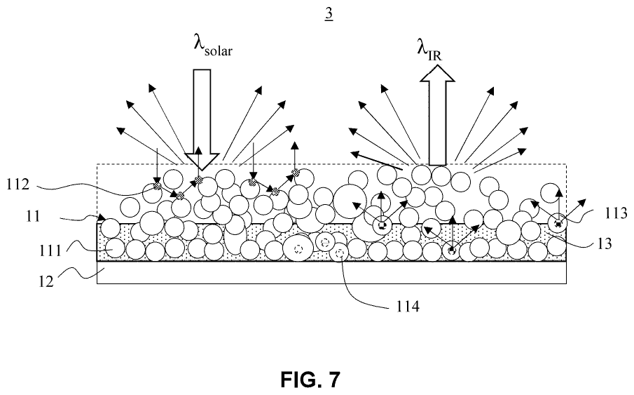

Referring to FIG. 7, it is a cross-sectional view of a composite thermal radiation heat dissipation device 3 according to a second preferred embodiment of the invention. The characteristics of the composite thermal radiation heat dissipation device 3 of the second preferred embodiment are substantially the same as the thermal radiation heat dissipation device 1 of the first preferred embodiment except the following: the composite thermal radiation heat dissipation device 3 includes a heat transfer layer 13 provided on the heat source 12. The heat transfer layer 13 fills gaps between the radiation heat transfer pile 11 and the heat source 12 and gaps among the polar dielectric material units 111 so as to increase heat transfer efficiency and decrease thermal resistance. The heat transfer layer 13 has a high thermal conduction coefficient. It is possible to adjust viscosity, flowability and expandability of the heat transfer layer 13. The heat transfer layer 13 includes but not limited to resin, silicone paste, silicone resin, heat transfer mud, silicone pad, heat transfer silicone cloth, heat transfer oil, heat transfer coating, plastics, heat transfer membrane, isolation membrane, isolator, interface material, double sided adhesive, heat transfer substrate, phase-changing material, heat transfer film, mica, pad, adhesive tape, and conduction metal pad. It is understood that in other embodiments, a material having a high heat transfer coefficient can be used to fill the gaps so as to increase heat transfer efficiency and decrease thermal resistance.

In the invention, the heat sources 12 and 22 may generate some amount of heat while it is executed by providing power supply. Heat is required to be sufficiently dissipated from the heat source. Otherwise, the heat source may malfunction. Examples of the heat sources are, but not limited to, central processing unit (CPU), chips in a smart phone, light-emitting diode (LED), chips in a solar cell panel, chips for automobile, chips for electronic components of a device used for outdoor purposes, and buildings. In applications such as electronic components used in a closed system, sunlight directly falls on the closed system. Further, both thermal convention and thermal conduction for heat dissipation are blocked in the closed system. Thus, internal temperature of the closed system increases quickly. Due to this, heating up of components of the system leads to premature failure and may cause failure of the entire circuit or system's performance. So, to conquer these negative aspects, heat dissipation devices must be provided for cooling purpose. It is envisaged by the invention that the thermal radiation heat dissipation device can greatly decrease internal temperature of the closed system exposed to direct sunlight with a minimum (almost no) energy consumption. In the invention, the closed system is defined as a system having little or even no thermal convection and thermal conduction (i.e., poor heat dissipation). The poor heat dissipation is defined as failure of the heat dissipation arrangement of the system. It is understood that no media is involved in thermal radiation and thus the invention utilizes passive thermal radiation to decrease temperature in order to eliminate drawbacks encountered by the conventional art.

In the invention, both the light scattering unit 112, 212 and the thermal radiation unit 113, 213 have different optical characteristics in response to different spectrum applications. In addition to objects or buildings directly hit by sunlight, the invention also applies to objects or buildings not hit by sunlight. It is understood that the invention has a significant heat dissipation performance for objects or buildings directly hit by sunlight. This is an improvement in comparison with the conventional art for dissipating heat from electric and electronic components.

The invention utilizes heat transfer units having acoustic phonons to transfer heat in comparison with the conventional method of transferring heat by means of metal. This is because the invention considers different optical characteristics of both solar radiation wavelength range of spectrum and black body radiation wavelength range of spectrum. Advantages of the invention include being capable of selecting a radiation heat transfer pile made of material having a specific resonant wavelength range, contributing to the control of spectrum, and producing a thermal radiation heat dissipation device having a wide wavelength range by incorporating a plurality of radiation heat transfer piles made of materials having different wavelength ranges. It is understood that polymers have various chemical bonding vibrational modes due to their functional groups including carbon, hydrogen, oxygen, nitrogen, and halogen atoms. Peaks of characteristic wavelengths of the functional groups are very close each other. Thus, their infrared wavelength ranges overlap to form an absorption peak having a wide half-wavelength. As a result, it is difficult of utilizing the conventional polymers to produce a radiation body having a broad wavelength range and high emissivity. Further, infrared wavelength ranges of polymers have weak radiant energy strength. In practice, thickness of the polymer is increased greatly. However, it inevitably increases thermal resistance.

In the invention, the polar dielectric material unit has both the thermal radiation unit and the heat transfer unit. With respect to thermal radiation heat transfer, the invention is envisaged to control wavelength range of emissivity by means of structure and selecting the thermal radiation unit to from a single or composite material of the black body radiation wavelength range. Thus, either a narrow or wide wavelength range radiation body is selected to accommodate different heat dissipation requirements. Further, the radiation heat transfer pile is advantageous due to strong mechanical properties, reliable ultraviolet, and high heat resistance. Thus, the radiation heat transfer pile is without drawbacks of the conventional polymer for radiation heat transfer purposes. Differences of the radiation heat transfer pile of the invention and the conventional polymer for radiation heat transfer purposes are detailed below. The conventional polymer may absorb ultraviolet of wavelength from 290 nm to 350 nm or infrared of wavelength from 1500 nm to 2500 nm. Thus, the conventional polymer cannot effectively decrease sunlight absorption, is subject to weathering, may absorb more sunlight due to excessive long periods of time exposed to ultraviolet, may be cracked, and may have degraded mechanical properties. Moreover, the conventional polymer does not withstand high temperature (e.g., less than 300° C.), is not flameproof, and is not appropriate for buildings. To the contrast, the radiation heat transfer pile of the invention can be mass produced, involves excellent technologies, can be easily molded, and is lightweight and inexpensive.

In the invention, the radiation heat transfer pile includes a plurality of polar dielectric material units shaped as a pile having a porous structure and a self-support structure. Thus, support for the radiation heat transfer pile is not required. The radiation heat transfer pile can be provided on an object for dissipating heat from the object. The heat dissipation performance is excellent. The radiation heat transfer pile can be nanoscale fibrous membrane made of silicon dioxide. Diameter of the polar dielectric material unit is nanoscale. Alternatively, it is implemented as a fibrous structure having a plurality of nanoparticles. A process of manufacturing the fibrous structure involves electrospinning. In detail, the process comprises but not limited to the steps of providing both a silicon oxide precursor solution; mixing tetraethyl orthosilicate and H₃PO₄ with deionized water and agitating same in room temperature to form a first solution; providing a polyvinyl alcohol (PVA) solution as polymer for electrospinning; adding PVA to the first solution and heating and agitating same until a uniformly solved second solution is formed; uniformly mixing the silicon oxide precursor solution and the second solution to form a composite solution; filling the composite solution in an injector and securing the injector to a syringe pump; subjecting the injector to an electrospinning machine, repulsion force between charges neutralizing surface tension of liquid so that the liquid drop becomes longer to shape as a conic drop; after voltage has increased to a value greater than a threshold, the repulsion force between charges being greater than surface tension of liquid to generate a flow injecting from the injector to a collector with the liquid being vaporized during the injection; collecting a formed fibrous structure on the collector; controlling process parameters including compositions and concentration of the solution, flow rate and applied voltage to control diameters of fibers of the fibrous structure; controlling injection rate and time to control thickness of membranes of the fibrous structure; heating the fibrous structure to remove the polymer to form a nanoscale radiation heat transfer pile fiber; and decreasing temperature to room temperature to remove polymer and produce a nanoscale fibrous membrane made of silicon dioxide. It is understood that above steps are for purposes of explanation only not for limiting the scope of the invention.

The thermal radiation heat dissipation device of the invention can be mass produced due to excellent thermal radiation heat transfer effect. When an object is covered by the thermal radiation heat dissipation device of the invention, heat can be effectively dissipated from the object with no electric power supply thereto. As a result, temperature of the object is sufficiently decreased.

While the invention has been described in terms of preferred embodiments, those skilled in the art will recognize that the invention can be practiced with modifications within the spirit and scope of the appended claims.

What is claimed is:

1. A thermal radiation heat dissipation device, comprising:
a radiation heat transfer pile including a plurality of polar dielectric material units of high energy gap, the polar dielectric material units each including at least one light scattering unit and a thermal radiation unit, wherein the light scattering unit is configured to interact with solar radiation to generate scattering of light; and wherein the thermal radiation unit is configured to interact with thermal radiation to increase strength of the thermal radiation.

2. The thermal radiation heat dissipation device as claimed in claim 1, wherein the polar dielectric material units are sub-wavelength structures.

3. The thermal radiation heat dissipation device as claimed in claim 2, wherein the sub-wavelength structures are piled to form a self-support structure.

4. The thermal radiation heat dissipation device as claimed in claim 2, wherein the sub-wavelength structures are piled to form a porous structure including a plurality of pores, and wherein thermal radiation passes through the pores to interact with the polar dielectric material units.

5. The thermal radiation heat dissipation device as claimed in claim 2, wherein the sub-wavelength structure is a fibrous structure having a nanometric diameter.

6. The thermal radiation heat dissipation device as claimed in claim 5, wherein the fibrous structure includes a plurality of nanoparticles.

7. The thermal radiation heat dissipation device as claimed in claim 1, wherein the polar dielectric material unit further comprises a heat transfer unit so that heat is configured to transfer between the polar dielectric material units through the heat transfer unit.

8. The thermal radiation heat dissipation device as claimed in claim 7, wherein the heat transfer unit transfers heat to the thermal radiation unit for increasing radiant energy strength of the thermal radiation unit.

9. A method of preparing the thermal radiation heat dissipation device as claimed in claim 1, the method comprising the steps of:
(a) providing both a solution having a precursor of fibrous material and a polymer for electrospinning;
(b) uniformly mixing the solutions to form a composite solution;
(c) subjecting the composite solution to an electrospinning machine for forming a fibrous structure by injection;
(d) controlling process parameters to adjust diameters of fibers of the fibrous structure and thickness of membranes of the fibrous structure; and
(e) heating the fibrous structure to remove polymer and produce a nanoscale fibrous membrane.

10. An electronic apparatus using the thermal radiation heat dissipation device as claimed in claim 1, wherein in a closed system the thermal radiation heat dissipation device is provided on an electronic component.
